(19) United States
(12) Patent Application Publication
(10) Pub. No.: US 2024/0387588 A1
(43) Pub. Date: Nov. 21, 2024

(54) IMAGE SENSOR PACKAGES AND METHOD THEREOF

(71) Applicant: OmniVision Technologies, Inc., Santa Clara, CA (US)

(72) Inventors: Wei-Feng Lin, Hsinchu City (TW); Chi-Chih Huang, Taoyuan City (TW); En-Chi Li, Hsinchu County (TW)

(21) Appl. No.: 18/320,606

(22) Filed: May 19, 2023

(51) Int. Cl. H01L 27/146

(52) U.S. Cl. CPC H01L 27/14636; H01L 27/14618; H01L 27/14683

(57) ABSTRACT

An image sensor package with a multi-step cavity formed in or on a substrate, which includes an image sensor bonded onto bottom of the multi-step cavity, and a cover glass placed and sealed on a lower portion of the multi-step cavity. Lower portion of the multi-step cavity includes at least a first and a second raised-step structures protruding from the bottom of the multi-step cavity, and the cover glass is placed and sealed over the first raised-step structure.

### TECHNICAL FIELD

The present invention relates to technology field of image sensor package, and more particularly, image sensor packages having multi-step cavity and method of manufacturing the same.

### BACKGROUND

High resolution image sensor modules have been widely applied in digital devices, for example digital cameras, cellular phones, security cameras, smartphones, tablets, etc., which are becoming more popular, and demands for small, light-weight and low-cost image sensor modules are increasing accordingly.

The image sensor modules include image sensors for converting image information into electrical information. Particularly, an image sensor may include semiconductor devices capable of converting photons to electrons to display and store images. In some embodiments, the image sensors can include charge coupled device (CCD), complementary metal oxide semiconductor (CMOS) image sensor, etc.

A conventional image sensor module may include a module substrate and an image sensor package disposed on the module substrate. As depicted in FIG. 1, which illustrates a cross-sectional side view of a conventional image sensor package 100. In FIG. 1, the image sensor package 100 includes a substrate 101, an image sensor 103 bonded to a recessed surface 105 of the substrate 101, and a cover glass 107 sealed to a top surface 109 of the substrate 101. The cover glass 107 provides protection over the image sensor 103 to avoid possible damages from moisture, dust, and other sources, where the cover glass 107 is sealed to the top surface 109 at a planar sealing interface 111 via adhesive 120.

Conventional image sensor package 100 shown in FIG. 1 has yield limitation by defect density, particularly for large die. Yield performance is typically depended on environment cleanness. However, current method of constructing image sensor package provides no rework solution after cover glass 107 been sealed.

According to the aforementioned drawback, an idea that can fix a cover glass by designing a stopper stage and perform image/electrical tests to verify validity of image sensor packages before performing the final sealing of the cover glass is therefore needed.

### SUMMARY OF THE INVENTION

In one aspect, the present invention provides an image sensor package with a multi-step cavity formed in or on a substrate, which includes an image sensor bonded onto bottom of the multi-step cavity, and a cover glass placed and sealed on a lower portion of the multi-step cavity. Lower portion of the multi-step cavity includes at least a first and a second raised-step structures protruding from the bottom of the multi-step cavity, and the cover glass is placed and sealed over the first raised-step structure.

The image sensor package with a multi-step cavity further includes a third raised-step structure over the first and the second raised-step structures.

In another aspect, the present invention provides a method for forming an image sensor package, which includes forming a multi-step cavity in or on a substrate, bonding an image sensor to a bottom of the multi-step cavity, assigning a placement stopper stage from lower portion of the multi-step cavity, placing a cover glass to the placement stopper stage, and performing test of the image sensor.

### BRIEF DESCRIPTION OF THE DRAWINGS

The components, characteristics and advantages of the present invention may be understood by the detailed descriptions of the preferred embodiments outlined in the specification and the drawings attached:

FIG. 1 shows a cross-sectional side view of a conventional image sensor package according to a prior art.

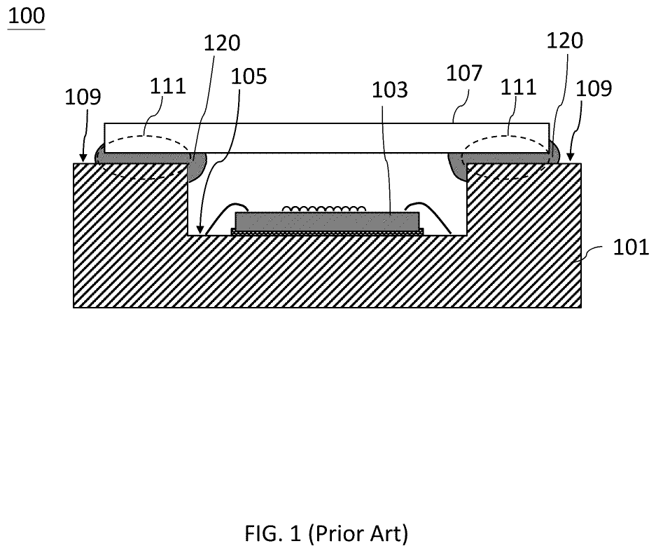

FIG. 2 shows a cross-sectional side view of an image sensor package according to one embodiment of the present invention.

FIG. 3 shows a cross-sectional side view of an image sensor package according to other embodiment of the present invention.

FIG. 4 illustrates a cross-sectional side view of an image sensor package according to yet another embodiment of the present invention.

FIG. 5 illustrates one exemplary method for forming an image sensor package according to one embodiment of the present invention.

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

To overcome the deficiency encountered by the conventional image sensor package module during its package process, novel image sensor packages and related manufacturing methods are proposed.

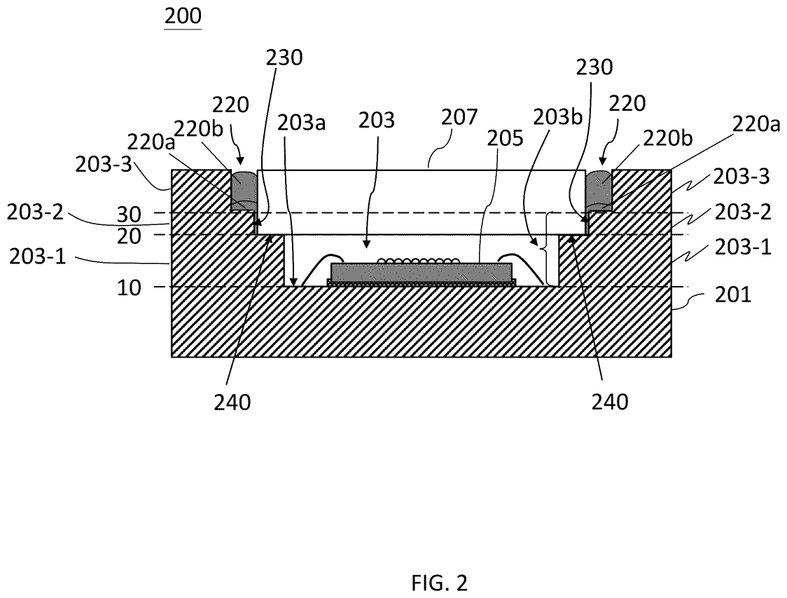

FIG. 2 illustrates one exemplary image sensor package 200, which includes a substrate 201, a multi-step cavity 203 formed in the substrate 201, an image sensor 205 bonded onto bottom 203a of the multi-step cavity 203, and a cover glass 207 placed and sealed on a lower portion 203b of the multi-step cavity 203. The lower portion 203b of the multi-step cavity 203 comprises at least a first raised-step structure 203-1 and a second raised-step structure 203-2 protruding from the bottom 203a of the multi-step cavity 203, where the second raised-step structure 203-2 includes side-wall surface 230 encompassing and adjoining a top surface 240 of the first raised-step structure 203-1. The cover glass 207 is placed (or interposed) and sealed over the first raised-step structure 203-1 via adhesive 220.

In some embodiments, the substrate 201 can be a ceramic substrate and the multi-step cavity 203 is formed within the ceramic substrate.

In some embodiments, the image sensor package 200 can further include a third raised-step structure 203-3 disposed over the second raised-step structure 203-2 to form an upper portion of the multi-step cavity 203.

To unambiguously point out the first, the second and the third raised-step structures in FIG. 2, three dashed lines 10, 20 and 30 are used to locate each of these three raised-step structures for indication purpose only. In this sense, the raised-step structure (or ledge) located between dashes lines 10 and 20 is the first raised-step structure 203-1; similarly, the raised-step structure (or ledge) located between dashes lines 20 and 30 is the second raised-step structure 203-2, and the raised-step structure (or ledge) located above dashes line 30 is the third raised-step structure 203-3.

In some embodiments, the adhesive 220 can be consisted of two kinds of glues with different viscosities, the bottom one 220a is used for prefixing purpose while the top one 220b is used for final fixing of the cover glass 207. The glue may be an epoxy or the like. In other alternatives, the glue may be optically or thermally cross-linkable, for example UV curable glue.

As shown in FIG. 2, there exists a cavity for the glue to fill within, which is formed between the side-wall surface of the third raised-step structure 203-3 and sides of the cover glass 207 while the cover glass 207 is placed, to act as glue cavity. The glue cavity can effectively prevent excessive glue from spilling onto the surface of the cover glass 207.

In some embodiments, an opening of the multi-step cavity for the cover glass 207 to be interposed, i.e., the opening enclosed by side-wall surface 230 of the second raised-step structure 203-2, is wider than that of the bottom of the multi-step cavity 203.

In some embodiments, the cover glass 207 is planar including a bottom surface disposed onto the top surface 240 of the first raised-step structure 203-1 and sides bonded to the side-wall surface 230 of the second raised-step structure 203-2 that is adjoint to top surface 240 of the the first raised-step structure 203-1.

In some embodiments, the ceramic substrate 201 may include oxide of aluminum, silicon, zinc, or the like.

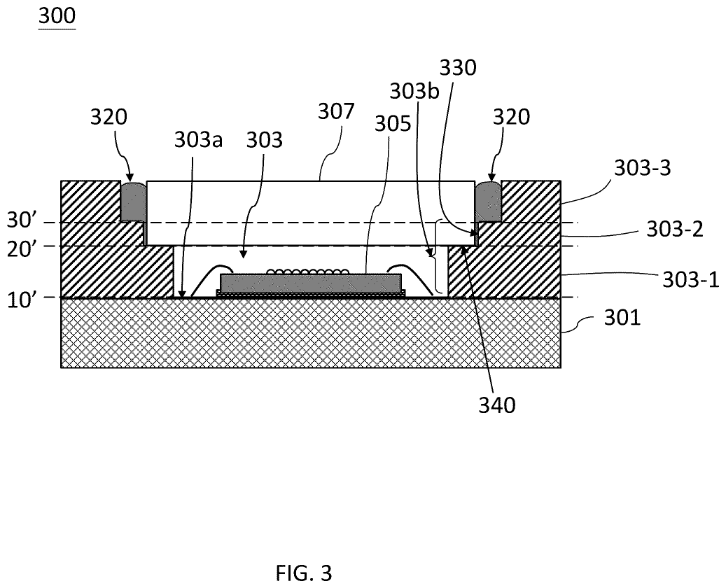

FIG. 3 illustrates other exemplary image sensor package 300, which includes a substrate 301, a multi-step cavity 303 formed on the substrate 301, an image sensor 305 bonded onto bottom 303a of the multi-step cavity 303, i.e. top surface of the substrate 301, and a cover glass 307 placed and sealed on a lower portion 303b of the multi-step cavity 303. The lower portion 303b of the multi-step cavity 303 comprises at least a first raised-step structure 303-1 and a second raised-step structure 303-2 protruding from the bottom 303a of the multi-step cavity 303, where the second raised-step structure 303-2 includes side-wall surface 330 encompassing and adjoining a top surface 340 of the first raised-step structure 303-1. The cover glass 307 is placed and sealed over the first raised-step structure 303-1 via adhesive 320.

In some embodiments, the substrate 301 may be a plastic substrate and the multi-step cavity 303 is formed over the plastic substrate and formed within a molding material.

In some embodiments, the image sensor package 300 can further include a third raised-step structure 303-3 disposed over the second raised-step structure 303-2 to form an upper portion of the multi-step cavity 303.

Similarly, three dashed lines 10′, 20′ and 30′ are used to locate each of these three raised-step structures. The raised-step structure (or ledge) located between dashes lines 10′ and 20′ is the first raised-step structure 303-1; the raised-step structure (or ledge) located between dashes lines 20′ and 30′ is the second raised-step structure 303-2, and the raised-step structure (or ledge) located above dashes line 30′ is the third raised-step structure 303-3.

In some embodiments, an opening of the multi-step cavity for the cover glass 307 to be interposed, i.e., the opening enclosed by side-wall surface 330 of the second raised-step structure 303-2, is wider than a that of the bottom of the multi-step cavity.

In some embodiments, the cover glass 307 is planar and includes a bottom surface disposed onto the top surface 340 of the first raised-step structure 303-1 and sides bonded to the side-wall surface 330 of the second raised-step structure 303-2 that is adjoint to top surface of the the first raised-step structure 303-1.

In some embodiments, the glue 320 may be an epoxy or the like. In other alternatives, the glue may be optically or thermally cross-linkable, for example UV curable glue.

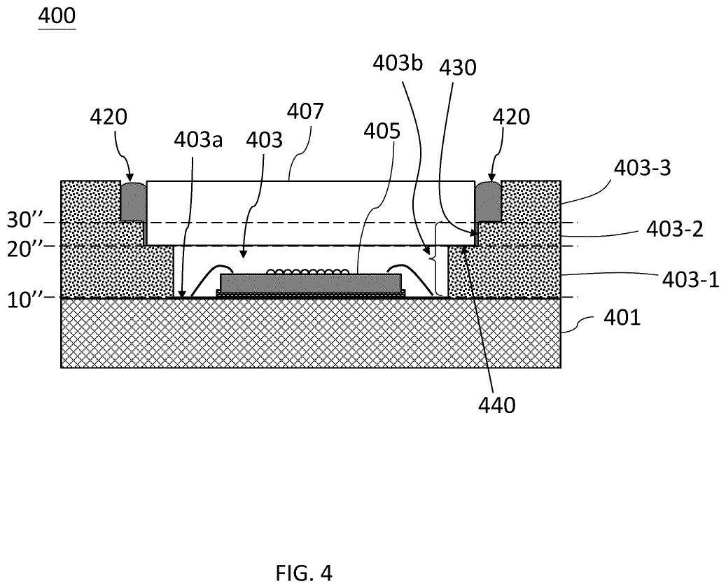

FIG. 4 illustrates yet other exemplary image sensor package 400, which includes a substrate 401, a multi-step cavity 403 formed on the substrate 401, an image sensor 405 bonded onto bottom 403a of the multi-step cavity 403, i.e. top surface of the substrate 401, and a cover glass 407 placed and sealed on a lower portion 403b of the multi-step cavity 403. The lower portion 403b of the multi-step cavity 403 comprises at least a first raised-step structure 403-1 and a second raised-step structure 403-2 protruding from the bottom 403a of the multi-step cavity 403, where the second raised-step structure 403-2 includes side-wall surface 430 encompassing and adjoining a top surface 440 of the first raised-step structure 403-1. The cover glass 407 is placed and sealed over the first raised-step structure 403-1 via adhesive 420.

In some embodiments, the substrate 401 may be a plastic substrate and the multi-step cavity 403 is formed over the plastic substrate 401 and within an organic material.

In some embodiments, the image sensor package 300 can further include a third raised-step structure 303-3 disposed over the second raised-step structure 303-2 to form an upper portion of the multi-step cavity.

Similarly, three dashed lines 10″, 20″ and 30″ are used to locate each of these three raised-step structures. The raised-step structure (or ledge) located between dashes lines 10″ and 20″ is the first raised-step structure 403-1; the raised-step structure (or ledge) located between dashes lines 20″ and 30″ is the second raised-step structure 403-2, and the raised-step structure (or ledge) located above dashes line 30″ is the third raised-step structure 403-3.

In some embodiments, an opening of the multi-step cavity for the cover glass 407 to be interposed, i.e., the opening enclosed by side-wall surface 430 of the second raised-step structure 403-2, is wider than a that of the bottom of the multi-step cavity.

In some embodiments, the cover glass 407 is planar and includes a bottom surface disposed onto the top surface 440 of the first raised-step structure 403-1 and sides bonded to the side-wall surface 430 of the second raised-step structure 403-2 that is adjoint to top surface of the the first raised-step structure 403-1.

In some embodiments, the glue 420 may be an epoxy or the like. In other alternatives, the glue may be optically or thermally cross-linkable, for example UV curable glue.

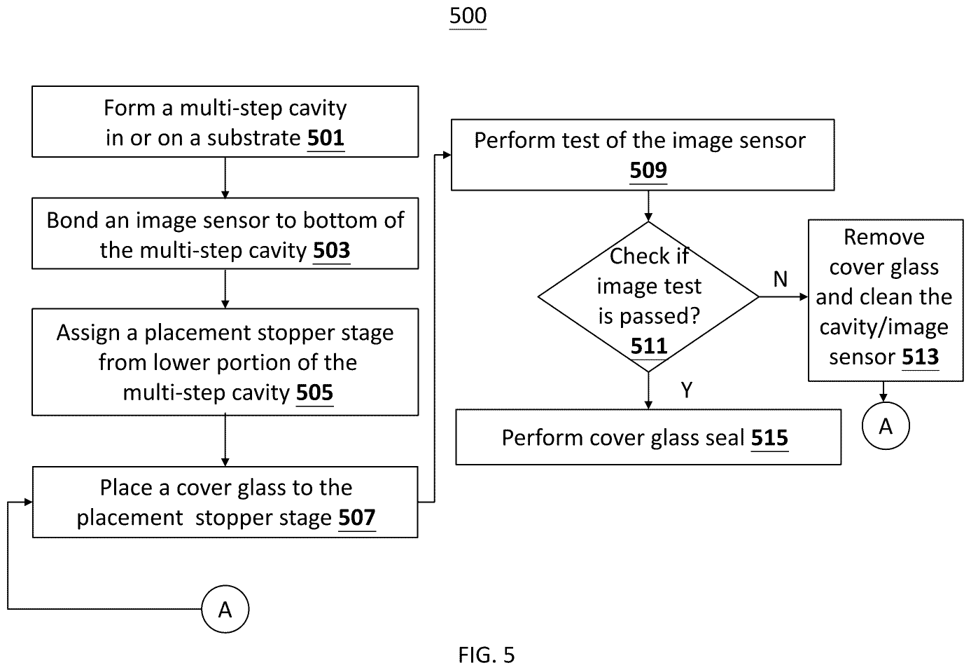

FIG. 5 illustrates one exemplary method 500 for forming an image sensor package. In an embodiment, method 500 includes a step 501 of forming a multi-step cavity in or on a substrate, this step can be referred to FIGS. 2-4 for the details about the multi-step cavity formed in a ceramic substrate (FIG. 2) or over a plastic substrate (FIGS. 3-4). In step 503, an image sensor is bonded to the bottom of the multi-step cavity. In step 505, a placement stopper stage, which can be raise-step structure (or ledge) of the multi-step cavity, is selected (or assigned) from lower portion of the multi-step cavity. In step 507, a cover glass is interposed (or placed) onto the placement stopper stage. In step 509, the image sensor is tested in image test station to verify a variety of imaging functions. In step 511, if the image test performed in step 509 is passed, proceed to step 515 for performing cover glass seal, otherwise in step 513 removing the cover glass and clean the cavity/image sensor then go back to step 507 to replace the cover glass to the placement stopper stage.

In an embodiment, the lower portion of the multi-step cavity as shown in FIGS. 2-4, which comprises at least a first and a second raised-step structures.

In an embodiment, the multi-step cavity as shown in FIGS. 2-4 may further include a third raised-step structure over the first and the second raised-step structures.

While various embodiments of the present invention have been described above, it should be understood that they have been presented by a way of example and not limitation. Numerous modifications and variations within the scope of the invention are possible. The present invention should only be defined in accordance with the following claims and their equivalents.

What is claimed is:

1. An image sensor package, comprising:
a multi-step cavity formed in or on a substrate;
an image sensor bonded onto bottom of said multi-step cavity; and
a cover glass placed and sealed on a lower portion of said multi-step cavity;
wherein said lower portion of said multi-step cavity includes at least a first and a second raised-step structures protruding from said bottom of said multi-step cavity, and said cover glass is placed and sealed over said first raised-step structure.

2. The image sensor package of claim 1, further including a third raised-step structure over said at least a first and a second raised-step structures.

3. The image sensor package of claim 2, wherein said second raised-step structure includes side-wall surface encompassing and adjoining a top surface of said first raised-step structure.

4. The image sensor package of claim 3, wherein said cover glass is planar and includes a bottom surface disposed onto said top surface of said first raised-step structure and sides bonded to said side-wall surface of said second raised-step structure.

5. The image sensor package of claim 1, wherein an opening of said multi-step cavity for said cover glass to be interposed is wider than an opening of bottom of said multi-step cavity.

6. The image sensor package of claim 1, wherein said substrate is a ceramic substrate.

7. The image sensor package of claim 6, wherein said multi-step cavity is formed within said ceramic substrate.

8. The image sensor package of claim 1, wherein said substrate is a plastic substrate.

9. The image sensor package of claim 8, wherein said multi-step cavity is formed within a molding material.

10. The image sensor package of claim 8, wherein said multi-step cavity is formed within an organic material.

11. A method for forming an image sensor package, comprising:
forming a multi-step cavity in or on a substrate;
bonding an image sensor to bottom of said multi-step cavity;
assigning a placement stopper stage from lower portion of said multi-step cavity;
placing a cover glass to said placement stopper stage; and
performing test of said image sensor.

12. The method of claim 11, wherein if said image sensor is passed said test, follow by sealing said cover glass, otherwise, removing said cover glass, placing said cover glass to said placement stopper stage again and then repeating said test.

13. The method of claim 11, wherein said lower portion of said multi-step cavity includes at least a first and a second raised-step structures protruding from said bottom of said multi-step cavity, and said placement stopper stage is formed over said first raised-step structure.

14. The method of claim 13, further including a third raised-step structure over said at least a first and a second raised-step structures.

15. The method of claim 11, wherein an opening of said placement stage for said cover glass to be interposed is wider than an opening of said bottom of said multi-step cavity.

16. The method of claim 12, in the step of sealing said cover glass including gluing said cover glass to said multi-step cavity.

17. The method of claim 16, wherein said cover glass is glued with UV curable glue.

18. The method of claim 11, wherein said substrate is a ceramic substrate.

19. The method of claim 18, wherein said multi-step cavity formed within a ceramic material.

20. The method of claim 11, wherein said substrate is a plastic substrate.
